(19) United States
(12) Patent Application Publication
(10) Pub. No.: US 2008/0217628 A1
(43) Pub. Date: Sep. 11, 2008

(54) LIGHT EMITTING DEVICE

(75) Inventors: Chung Hoon LEE, Ansan-si (KR); Jae Ho LEE, Ansan-si (KR); Dae Won KIM, Ansan-si (KR)

Correspondence Address: MARGER JOHNSON & MCCOLLOM, P.C., 210 SW MORRISON STREET, SUITE 400, PORTLAND, OR, 97204, US

(73) Assignee: SEOUL SEMICONDUCTOR CO., LTD., Seoul (KR)

(21) Appl. No.: 12/042,934

(22) Filed: Mar. 5, 2008

Related U.S. Application Data
(60) Provisional application No. 60/893,085, filed on Mar. 5, 2007.

(51) Int. Cl. H01L 33/00

(52) U.S. Cl. 257/88; 257/E33.001

(57) ABSTRACT

The present invention relates to a light emitting device having a light emitting diode package with a plurality of light emitting cells and an integrated electronic element formed on the same substrate. The light emitting device comprises a substrate, a light emitting cell block having a first array with a plurality of light emitting cells formed on one region of the substrate arranged therein, a second array formed on the same region as the first array, and electrodes for AC power connecting the first and second arrays in reverse parallel; and at least one integrated electronic element formed on another region of the same substrate as the light emitting cell block.

### CROSS-REFERENCE TO RELATED APPLICATION

The present application claims priority from U.S. Provisional Patent Application Ser. No. 60/893,085, filed Mar. 5, 2007, incorporated herein by reference in its entirety for all purposes.

### FIELD OF THE INVENTION

The present invention relates to a light emitting device, in which a light emitting diode package having a plurality of light emitting cells and an integrated electronic element are formed on the same substrate, and more particularly, to a light emitting device, which includes a substrate, a light emitting cell block having a first array with a plurality of light emitting cells formed on one region of the substrate arranged therein, a second array formed on the same region as the first array and electrodes for AC power connecting the first and second arrays in reverse parallel, and at least one integrated electronic element on another region of the substrate.

### BACKGROUND OF THE INVENTION

In general, a light emitting diode (LED) means a light emitting element that produces minority carriers (electrons or holes) by means of a p-n junction structure of a compound semiconductor and emits predetermined light due to recombination of the minority carriers. Such a LED is mounted in the form of a light emitting chip on a top surface of a PCB or lead terminal and is electrically connected to the PCB or lead terminal, and a molding member is formed on the top surface of the PCB or lead terminal using a fluorescent material, resin such as epoxy, or the like. Thus, the LED is used for a display device, a backlight, a lighting apparatus or the like, depending on its object and usage. Recently, studies for applying the LED to a general illuminator have been actively conducted.

FIG. 1 is a schematic view illustrating a conventional light emitting device.

Referring to FIG. 1, the light emitting device for general illumination is manufactured by connecting a plurality of light emitting elements 10a to 10c in series each of which has a light emitting chip mounted thereon. To this end, the plurality of light emitting elements 10a to 10c are arranged in series, and then, light emitting chips in the light emitting elements 10a to 10c are electrically connected in series though a metal wiring process. Such a manufacturing method has been disclosed in U.S. Pat. No. 5,463,280.

The light emitting device using such LEDs has less electric power consumption and a longer life span of several to several ten times as compared with a conventional light bulb or fluorescent lamp, thereby having the advantage of the reduced electric power consumption and excellent durability.

However, an LED, which is a semiconductor device in which emits light through recombination of electrons and holes using a P-N junction structure of a semiconductor, is generally driven by a current flowing in one direction. In order to use such an LED in a general illuminator, a DC-to-AC converter is required. Such a DC-to-AC converter makes it difficult to commercialize the LED for general illumination. Therefore, an LED capable of being driven by AC power without a DC-to-AC converter is required to use the LED for general illumination.

Further, there is a problem in that an additional electronic element should be electrically connected to a light emitting element for the purpose of a voltage drop of AC power of 100V to 240V supplied from a power source to the light emitting element, and the electronic element may change total resistance due to self-resistance possessed by the electronic element itself.

There is also a problem in that the reliability of an LED is lowered and the life span thereof is reduced due to a leakage current through a DC-to-AC converter, transistor, diode or the like, which is an additional electronic element connected to the LED.

In addition, since the conventional light emitting device becomes unstable because of abrupt voltage rise caused by electro static discharge (ESD), surge caused by lightning or the like, there is a problem the life span of an LED chip is reduced. To this end, an additional protection device should be provided.

The present invention is conceived to solve the aforementioned problems in the prior art. Accordingly, an object of the present invention is to provide a light emitting device integrated without an additional DC-to-AC converter by connecting a light emitting cell block with a plurality of light emitting cells arranged therein to an electronic element, such as a transistor or diode, formed on the same substrate in which the light emitting cell block is mounted.

Another object of the present invention is to provide a light emitting device in which a light emitting cell block and an integrated electronic element are formed on the same substrate, thereby solving the problem that the reliability of an LED is lowered and the life span thereof is reduced due to the self resistance and leakage current of an electronic element itself, such as a resistor element or discharge element, which is provided separately from the LED.

A further object of the present invention is to provide a light emitting device wherein an integrated electronic element is formed together with a light emitting cell block on the same substrate, so that a manufacturing process can be simplified, manufacturing costs can be reduced, mass production is possible, and compact products can be advantageously manufactured.

According to an aspect of the present invention, there is provided a light emitting device, comprising: a substrate; a light emitting cell block having a first array with a plurality of light emitting cells formed on one region of the substrate arranged therein, a second array formed on the same region as the first array, and electrodes for AC power connecting the first and second arrays in reverse parallel; and at least one integrated electronic element formed on another region of the same substrate as the light emitting cell block.

The light emitting device may further comprise an insulation layer for electrically separating the light emitting cell block and the electronic element, which are formed on the substrate, from each other.

Each of the plurality of light emitting cells may comprise a first conductive semiconductor layer formed on the substrate, a second conductive semiconductor layer and a light emitting layer containing In interposed between the first and second conductive semiconductor layers.

The light emitting cells in the respective first and second arrays may be the same in number and are zigzag arranged, and the first and second arrays may further include common electrodes for connecting the first and second arrays to one another.

The electronic element may be a transistor for controlling the light emitting cell block formed on the same substrate.

The transistor can be fabricated by growing field oxides on the substrate to define an active region and field regions, forming a gate oxide on the surface of the substrate in the active region, forming a gate on the gate oxide, and then injecting ions to both sides of the gate to form a source/drain.

In another embodiment of the present invention, conventional methods of fabricating CMOS are also possible, where an N-type well region is formed on a silicon substrate, a gate is formed on the N-type well region, and then p-type ions are injected to form a source/drain.

Preferably, the transistor includes an source, a drain and a gate at another side of the substrate on which the light emitting cell block is formed, the source, the drain and the gate being formed with carbon nano tubes and gold (Au).

The electrode element may be at least any one of a rectifying diode, a switching diode, a zener diode, a variable capacitance diode, a light receiving (photo) diode and a varistor diode.

The light emitting cell block may include a connection member in an electrical, mechanical or chemical form for connecting the light emitting cell block to the electronic element formed on the same substrate.

### DESCRIPTION OF THE DRAWINGS

The above and other objects, features and advantages of the present invention will become apparent from the following description of preferred embodiments given in conjunction with the accompanying drawings, in which:

FIG. 1 is a schematic view illustrating a conventional light emitting device;

FIGS. 2a and 2b are sectional views illustrating a light emitting diode chip having light emitting cells connected in series to one another on a substrate according to the present invention; and

FIG. 3 is a sectional view illustrating a light emitting device according to the present invention.

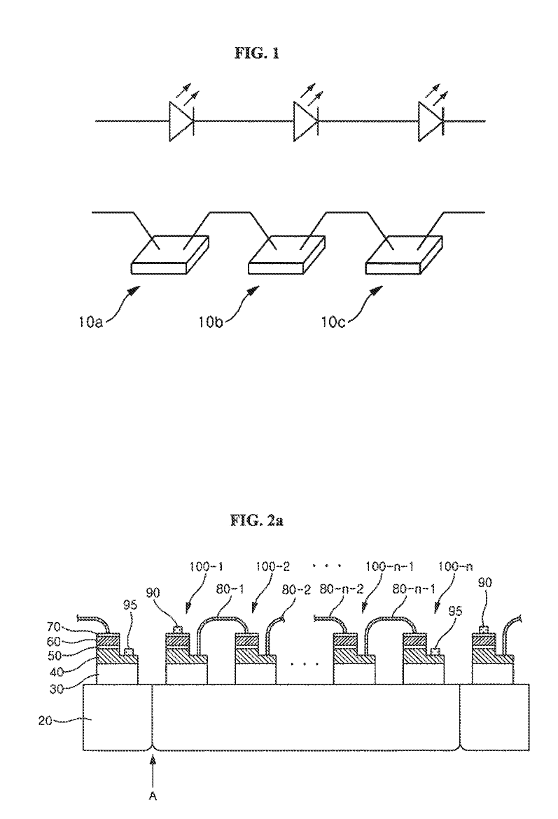

### DETAILED DESCRIPTION

Hereinafter, preferred embodiments of the present invention will be described in detail with reference to the accompanying drawings. However, the present invention is not limited to the embodiments but may be implemented into different forms. These embodiments are provided only for illustrative purposes and for full understanding of the scope of the present invention by those skilled in the art. Throughout the drawings, like elements are designated by like reference numerals.

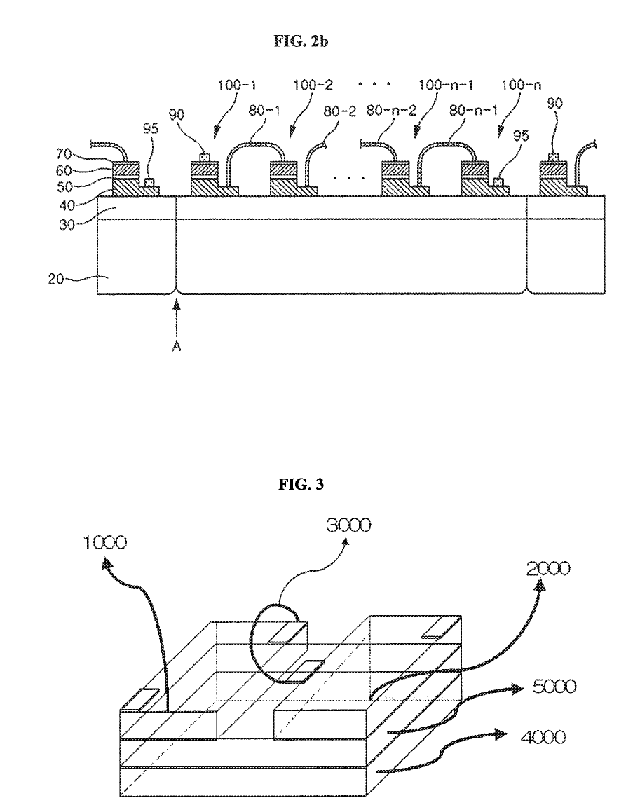

FIGS. 2a and 2b are sectional views illustrating a light emitting diode (LED) chip having light emitting cells connected in series to one another on a substrate according to the present invention.

Referring to FIGS. 2a and 2b, the LED chip of the present invention has a plurality of light emitting cells 100-1 to 100n, which are spaced apart from one another on a substrate 20 and connected in series to one another through wires 80-1 to 80-n−1. That is, the LED chip comprises the plurality of light emitting cells 100 (100-1 to 100-n) in which N-type and P-type semiconductor layers 40 and 60 respectively formed in adjacent each pair of the light emitting cells 100-1 to 100-n are electrically connected to each other, an N-type pad 95 is formed on the N-type semiconductor layer 40 of the light emitting cell 100-n positioned at one end of the substrate 20, and a P-type pad 90 is formed on the P-type semiconductor layer 60 of the light emitting cell 100-1 positioned at the other end of the substrate 20.

The N-type and P-type semiconductor layers 40 and 60 respectively formed in adjacent each pair of the light emitting cells 100-1 to 100-n are electrically connected to each other through one of the metallic wires 80. Further, in the present invention, it is effective to form the plurality of light emitting cells 100-1 to 100-n of which the number corresponds to an AC voltage capable of driving the light emitting cells connected in series. In the present invention, the number of light emitting cells 100 connected in series may vary depending on voltage/current for driving a single light emitting cell 100 and AC driving voltage applied to the LED chip for illumination.

The N-type and P-type semiconductor layers 40 and 60 respectively formed in adjacent each pair of the light emitting cells 100-1 to 100-n are electrically connected to each other through the metallic wires 80, so that the light emitting cells 100-1 to 100-n are formed into a light emitting cell array. For the purpose of an optimal arrangement in a predetermined space, a plurality of light emitting cell arrays, each of which is formed in this manner and has the light emitting cells zigzag arranged, are formed into a matrix.

Further, the light emitting cell arrays may include common electrodes for connecting the light emitting cells respectively provided in the light emitting cell arrays to each other.

For example, in the LED chip having the first to n-th light emitting cells 100-1 to 100-n connected in series as shown in FIG. 2a, the P-type pad 90 is formed on the P-type semiconductor layer 60 of the first light emitting cell 100-1, and the N-type semiconductor layer 40 of the first light emitting cell 100-1 and the P-type semiconductor layer 60 of the second light emitting cell 100-2 are connected to each other through the first wire 80-1. Further, the N-type semiconductor layer 40 of the second light emitting cell 100-2 and the P-type semiconductor layer (not shown) of the third light emitting cell (not shown) are connected to each other through the second wire 80-2. In addition, the N-type semiconductor layer (not shown) of the (n−2)-th light emitting cell (not shown) and the P-type semiconductor layer 60 of the (n−1)-th light emitting cell 100-n−1 are connected to each other through the (n−2)-th wire 80-n−2, and the N-type semiconductor layer 40 of the (n−1)-th light emitting cell 100-n−1 and the P-type semiconductor layer 60 of the n-th light emitting cell 100-n are connected to each other through the (n−1)-th wire 80-n−1. Further, the N-type pad 95 is formed on the N-type semiconductor layer 40 of the n-th light emitting cell 100-n.

The substrate 20 in the present invention may be a substrate on which a plurality of LED chips can be manufactured. Accordingly, “A” shown in FIGS. 2a and 2b designates a cutting zone for cutting the plurality of LED chips individually.

Hereinafter, a method of manufacturing the LED chip having the light emitting cells connected in series will be described.

A buffer layer 30, the N-type semiconductor layer 40, an active layer 50 and the P-type semiconductor layer 60 are sequentially grown on the substrate 20. A transparent electrode layer 70 may be further formed on the P-type semiconductor layer 60. The substrate 20 may be a sapphire (Al₂O₃), silicon carbide (SiC), zinc oxide (ZnO), silicon (Si), gallium arsenide (GaAs), gallium phosphide (GaP), lithium alumina (LiAl₂O₃), boron nitride (BN), aluminum nitride (AlN) or gallium nitride (GaN) substrate. The substrate 20 may be selected depending on a material of a semiconductor layer to be formed on the substrate 20. In a case where a gallium nitride based semiconductor layer is used, it is preferred that the substrate 20 be a sapphire or silicon carbide substrate.

The buffer layer 30 is a layer for reducing lattice mismatch between the substrate 20 and the subsequent layers upon growth of crystals. For example, the buffer layer 30 may be a gallium nitride (GaN) layer. In a case where a SiC substrate is conductive, it is preferred that the buffer layer 30 be formed of an insulation layer (not shown) and formed of semi-insulative GaN.

The N-type semiconductor layer 40 is a layer in which electrons are produced, and is composed of an N-type compound semiconductor layer and an N-type cladding layer. At this time, GaN doped with N-type impurities may be used for the N-type compound semiconductor layer. The P-type semiconductor layer 60 is a layer in which holes are produced, and is composed of a P-type cladding layer and a P-type compound semiconductor layer. At this time, AlGaN doped with P-type impurities may be used for the P-type compound semiconductor layer.

The active layer 50 is a region in which a predetermined band gap and a quantum well are formed and then electrons and holes are recombined. The active layer 50 may include a GaN based semiconductor layer containing In. Further, the wavelength of emitted light, which is generated by the combination of an electron and a hole, varies depending on the kind of a material constituting the active layer 50. Therefore, it is preferred that a semiconductor material contained in the active layer 50 be controlled depending on a desired wavelength.

Thereafter, the P-type semiconductor layer 60 and the active layer 50 are patterned through a photo and etching process, so that portions of the N-type semiconductor layer 40 are exposed. Further, portions of the exposed N-type semiconductor layer 40 are removed, so that the respective light emitting cells 100 are electrically isolated from one another. At this time, the exposed portions of the buffer layer 30 may be removed, so that a top surface of the substrate 20 is partially exposed as shown in FIG. 2a, or an etching process may be stopped at the buffer layer 30 as shown in FIG. 2b.

Thereafter, the conductive wires 80-1 to 80-n for electrically connecting the N-type semiconductor layers 40 and the P-type semiconductor layers 60 of the adjacent pairs of the light emitting cells 100-1 to 100-n are formed through a bridge process, step-cover process, or the like. The conductive wires 80-1 to 80-n are formed of a conductive material and preferably of a silicon or a semiconductor compound doped with metal or impurities.

The bridge process, which is also referred to as an air bridge process, will be briefly described. A photoresist is first formed on the substrate with the light emitting cells formed thereon, and a first photoresist pattern with openings, through which the exposed N-type semiconductor layer and the electrode layer on the top surface of the P-type semiconductor layer are exposed, is then formed through a light exposing process. Then, a metallic material layer is formed to be thin using an e-beam evaporation process or the like. The metallic material layer is formed in the openings and on the entire top surface of the first photoresist pattern. Subsequently, a second photoresist pattern for exposing regions between adjacent light emitting cells to be connected to each other and the metallic material layer of the openings is further formed on the top surface of the first photoresist pattern. Thereafter, gold (Au) or the like is formed through a plating process, and the first and second photoresist patterns are removed. As a result, the wires respectively connecting the adjacent light emitting cells to one another are left, and the other metallic material layer and the first and second photoresist patterns are all removed. Therefore, the light emitting cells are connected through the wires in the shape of a bridge.

Meanwhile, the step-cover process includes a process of forming an insulation layer on the substrate having light emitting cells formed thereon. The insulation layer is patterned through a photo and etching process to form openings, through which the N-type semiconductor layer and the electrode layer on the top surface of the P-type semiconductor layer are exposed. Subsequently, a metal layer, with which the openings are filled and the top surface of the insulation layer is covered, is formed using an e-beam evaporation process or the like. Then, the metal layer is patterned through a photo and etching process to form the wires for connecting the adjacent light emitting cells to one another. Various modifications are possible in such a step-cover process. Since a wire is supported by an insulation layer if the step-cover process is used, the reliability of the wire can be enhanced.

Meanwhile, P-type and N-type pads 90 and 95 are formed on the P-type and N-type semiconductor layers 60 and 40 of the light emitting cells 100-1 and 100-n positioned at both ends of the substrate 20, respectively. The P-type and N-type pads 90 and 95 correspond to electrodes for AC power through which light emitting cell arrays each having the plurality of light emitting cells 100-1 to 100-n formed therein are connected in reverse parallel.

The aforementioned method of manufacturing the LED chip is only a specific embodiment of the present invention, and the present invention is not limited thereto. That is, various processes and manufacturing methods may be modified or added depending on the characteristics of the element and convenience of a process thereof.

For example, a plurality of vertical light emitting cells, each of which has an N-type electrode, an N-type semiconductor layer, an active layer, a P-type semiconductor layer and a P-type electrode sequentially laminated therein, are formed on a substrate, or light emitting cells with such a structure are bonded on a substrate to be arranged. Thereafter, the plurality of light emitting cells are connected in series to one another by connecting N-type and P-type electrodes of adjacent pairs of the light emitting cells through wires, so that an LED chip can be manufactured. It will be apparent that the vertical light emitting cell should not be formed to have the structure limited to the aforementioned example but may be formed to have various structures. Further, after a plurality of light emitting cells are formed on a substrate, the light emitting cells are boned on an additional host substrate, and the substrate is removed using laser or through a chemical mechanical polishing process. Accordingly, the plurality of light emitting cells can be formed on the host substrate. Then, the adjacent pairs of the light emitting cells may be connected in series through wires.

Each of the light emitting cells 100 includes the N-type semiconductor layer 40, the active layer 50 and the P-type semiconductor layer, which are sequentially laminated on the substrate 20. The buffer layer 30 is interposed between the substrate 20 and the light emitting cell 100. Each of the light emitting cells 100 includes the transparent electrode layer 70 formed on the P-type semiconductor layer 60. Further, in case of a vertical light emitting cell, an N-type electrode is included, which is positioned under the N-type semiconductor layer.

The N-type and P-type bonding pads, which are pads for electrically connecting the light emitting cell 100 and an external metallic wire or bonding wire, may be formed to have a structure with laminated Ti/Au. The bonding pads may be formed on the N-type and P-type semiconductor layers of each of all the light emitting cells. Further, the aforementioned transparent electrode layer 70 serves to uniformly transmit voltage input through the P-type boding pad to the P-type semiconductor layer 60.

FIG. 3 is a sectional view illustrating a light emitting device according to the present invention.

In the light emitting device shown in FIG. 3, a light emitting cell block 1000 having light emitting cell arrays, each of which includes a plurality of light emitting cells 100, and an electronic element 2000 are formed on a bulk type substrate 4000.

The plurality of light emitting cells 100 constitute the light emitting cell block 1000 of a bulk type by separating a buffer layer 30 or insulation layer from a substrate 20 through an LLO (Laser Lift Off) method, which is a separating method using a laser radiated onto a bottom surface of the substrate 20, a heating process of heating the substrate 20 and a contact portion between the substrate 20 and the buffer layer 30, or a chemical treatment such as an etching or wet process.

The light emitting cell block 1000 is bonded on an insulation layer 5000 through an adhesive layer (not shown) at one side of the upper end of the bulk type substrate 4000, and the electrode element 2000 formed at another side of the upper end of the bulk type substrate 4000 is bonded on the insulation layer 5000 through the adhesive layer (not shown).

In a case where an insulation layer made of a insulative material or an insulative or semi-insulative buffer layer 30 is formed under the surface of the light emitting cell block 1000 bonded to the substrate 4000, the insulation layer 5000 formed on the bulk type substrate 4000 may be omitted.

At least any one of a transistor, a rectifying diode, a switching diode, a zener diode, a variable-capacitance diode, a light receiving (photo) diode and a varistor diode may be selectively used as the electronic element 2000.

The electronic element 2000 may be a transistor for controlling the light emitting cell block 1000 formed on the same substrate. The transistor can be fabricated by growing field oxides on the substrate to define an active region and field regions, forming a gate oxide on the surface of the substrate in the active region, forming a gate on the gate oxide, and then injecting ions to both sides of the gate to form a source/drain.

In another embodiment of the present invention, conventional methods of fabricating CMOS are also possible, where an N-type well region is formed on a silicon substrate, a gate is formed on the N-type well region, and then p-type ions are injected to form a source/drain.

The transistor among the electronic elements 2000 may be formed by scattering carbon nano tubes on the other side of the substrate 4000 using an ultrasonic or inkjet method and then forming source and drain electrodes made of gold (Au) on the substrate 4000.

As described above, the present invention has an advantage in that an integrated electronic element is formed together with a light emitting cell block on the same substrate, so that a manufacturing process can be simplified, manufacturing costs can be reduced, mass production is possible, and compact products can be easily manufactured.

Further, self resistance and leakage current of an electronic element itself, such as a resistor element or discharge element, which is provided separately from an LED, is prevented, whereby the reliability of a light emitting device can be enhanced and the life span thereof can be prevented from being reduced.

The scope of the present invention is not limited to the embodiment described and illustrated above but is defined by the appended claims. It will be apparent that those skilled in the art can make various modifications and changes thereto within the scope of the invention defined by the claims. Therefore, the true scope of the present invention should be defined by the technical spirit of the appended claims.

1. A light emitting device, comprising:
a substrate;
a light emitting cell block having a first array with a plurality of light emitting cells formed on one region of the substrate arranged therein, a second array formed on the same region as the first array, and electrodes for AC power connecting the first and second arrays in reverse parallel; and
at least one integrated electronic element formed on another region of the same substrate as the light emitting cell block.

2. The light emitting device as claimed in claim 1, further comprising an insulation layer for electrically separating the light emitting cell block and the electronic element, which are formed on the substrate, from each other.

3. The light emitting device as claimed in claim 1, wherein each of the plurality of light emitting cells comprises a first conductive semiconductor layer formed on the substrate, a second conductive semiconductor layer and a light emitting layer containing In interposed between the first and second conductive semiconductor layers.

4. The light emitting device as claimed in claim 1, wherein the light emitting cells in the respective first and second arrays are the same in number and are zigzag arranged, and the first and second arrays further includes common electrodes for connecting the first and second arrays to one another.

5. The light emitting device as claimed in claim 1, wherein the electronic element is a transistor for controlling the light emitting cell block formed on the same substrate.

6. The light emitting device as claimed in claim 5, wherein the transistor is fabricated by growing field oxides on the substrate to define an active region and field regions, forming a gate oxide on the surface of the substrate in the active region, forming a gate on the gate oxide, and then injecting ions to both sides of the gate to form a source/drain.

7. The light emitting device as claimed in claim 5, wherein the transistor includes an source, a drain and a gate at another side of the substrate on which the light emitting cell block is formed, the source, the drain and the gate being formed with carbon nano tubes and gold (Au).

8. The light emitting device as claimed in claim 1, wherein the electrode element is at least any one of a rectifying diode, a switching diode, a zener diode, a variable capacitance diode, a light receiving (photo) diode and a varistor diode.

9. The light emitting device as claimed in claim 1, wherein the light emitting cell block includes a connection member in an electrical, mechanical or chemical form for connecting the light emitting cell block to the electronic element formed on the same substrate.
